(19) United States
(12) Patent Application Publication
(10) Pub. No.: US 2014/0063935 A1
(43) Pub. Date: Mar. 6, 2014

(54) SEMICONDUCTOR MEMORY DEVICE HAVING VERTICAL CHANNELS, MEMORY SYSTEM HAVING THE SAME, AND METHOD OF FABRICATING THE SAME

(71) Applicant: SK HYNIX INC., Gyeonggi-do (KR)

(72) Inventor: Sun Mi PARK, Seoul (KR)

(73) Assignee: SK HYNIX INC., Gyeonggi-do (KR)

(21) Appl. No.: 13/715,756

(22) Filed: Dec. 14, 2012

(30) Foreign Application Priority Data
Aug. 29, 2012 (KR) 10-2012-0095045

(51) Int. Cl. H01L 29/78; G11C 11/40; H01L 29/66

(52) U.S. Cl. CPC H01L 29/78; H01L 29/66477; G11C 11/40
USPC 365/184; 257/314; 438/589

(57) ABSTRACT

A semiconductor memory device, a memory system having the same, and a method of fabricating the same are provided. The semiconductor memory device includes a vertical channel layer protruding from a surface of a substrate, a tunnel insulating layer and a charge storage layer, which are surrounding the vertical channel layer, a blocking layer surrounding the charge storage layer, interlayer insulating layers stacked along the blocking layer, and conductive layers interposed between the interlayer insulating layers. The blocking layer includes a metal oxide layer.

### CROSS-REFERENCE TO RELATED APPLICATION

This application claims priority to and the benefit of Korean Patent Application No. 10-2012-0095045, filed on Aug. 29, 2012, the disclosure of which is incorporated herein by reference in its entirety.

### BACKGROUND

1. Field

Exemplary embodiments of the present invention relates to a semiconductor memory device having vertical channels.

2. Discussion of Related Art

Semiconductor memory devices have developed to have high integration and store large amounts of data. Generally, memory device arranged in a row direction on a semiconductor substrate is called a two-dimensional structured memory device. In order to store a large amount of data, the two-dimensional structured memory device requires the semiconductor substrate to have a wider space. However, the improvement of integration in the two-dimensional structured memory device is limited due to a limitation in space of the semiconductor substrate, and may increase interference or disturbance between adjacent devices. As a result, it is becoming more difficult to implement a multi-level cell (MLC) operation through which it is easy to store a large amount of data in the two-dimensional structured memory device. To overcome the limitations of the two-dimensional structured memory device, three-dimensional structured memory devices are being developed.

The three-dimensional structured memory devices includes a channel substantially perpendicular to the semiconductor substrate since memory cells usually arranged only in a row direction are stacked perpendicularly to the semiconductor substrate. Accordingly, the three-dimensional structured memory devices are more effective in achieving high integration and large capacity than the two-dimensional structured memory device.

Brief description of a method of fabricating a three-dimensional memory device is as follows.

A plurality of sacrificial layers and first material layers are formed on a semiconductor substrate, and a plurality of vertical channel holes are formed in areas for forming vertical channels. A memory stacked-layer having a blocking layer, charge storage layer, and tunnel insulating layer, and a vertical channel layer are formed along inner walls of the vertical channel holes. A slit is formed between the vertical channel holes, and recesses are formed between the first material layers by removing the sacrificial layers exposed inside the slit. At this point, the blocking layer, a part of the memory stacked-layer, is exposed through the recesses, and therefore damaged during an etch process for removing the sacrificial layers. Usually, since the sacrificial layers are formed of a nitride layer, a wet etch process using a phosphoric acid solution is performed as the etch process for removing the sacrificial layers because the etch rate for nitride layer is fast. However, although the etch rate of a silicon oxide is slower than that of the nitride layer, a silicon oxide layer usually used as the blocking layer may still be etched by the phosphoric acid solution. Accordingly, when the blocking layer is damaged in the etch process, the charge storage layer may be exposed and the thickness of the memory stacked-layer may decrease. In order to compensate for such damage, since a process of additionally forming the blocking layer should be conducted, the time and costs for the fabrication process may increase.

### SUMMARY OF THE INVENTION

Exemplary embodiments of the present invention are directed to a method of fabricating a semiconductor memory device preventing a damage from an etch process in a process of fabricating a memory device having a vertical channel structure.

One aspect of the exemplary embodiment of the present invention provides a semiconductor memory device including a vertical channel layer protruding from a surface of a substrate, a tunnel insulating layer and a charge storage layer, which are surrounding the vertical channel layer, a blocking layer surrounding the charge storage layer, interlayer insulating layers stacked along the blocking layer, and conductive layers interposed between the interlayer insulating layers. The blocking layer includes a metal oxide layer.

Another aspect of the exemplary embodiment of the present invention provides a method of fabricating a semiconductor memory device including alternately forming a plurality of interlayer insulating layers and sacrificial layers over a substrate, forming vertical channel holes passing through the interlayer insulating layers and sacrificial layers substantially perpendicular to the substrate, forming blocking layers, charge storage layers, tunnel insulating layers, and vertical channel layers along inner walls of the vertical channel holes, etching the interlayer insulating layers and the sacrificial layers to form a slit between the vertical channel layers, removing the sacrificial layers exposed through the slit to form recesses between the interlayer insulating layers, forming a conductive layer in the recesses, and filling the slit with an insulating layer. The blocking layer includes a metal oxide layer.

Still another aspect of the exemplary embodiment of the present invention provides a memory system including a semiconductor memory device including a vertical channel layer protruding from a surface of a substrate, a tunnel insulating layer and a charge storage layer, which are surrounding the vertical channel layer, a blocking layer surrounding the charge storage layer, interlayer insulating layers stacked along the blocking layer, and conductive layers interposed between the interlayer insulating layers, and a memory controller controlling the semiconductor memory device. The blocking layer includes a metal oxide layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIGS. 1A to 1I are cross-sectional views illustrating a method of fabricating a semiconductor device according to an exemplary embodiment of the present invention;

FIG. 2 is a block diagram illustrating a semiconductor memory device according to an exemplary embodiment of the present invention; and

FIG. 3 is a block diagram schematically illustrating a memory system according to the present invention.

### DETAILED DESCRIPTION OF EMBODIMENTS

The present invention will be described more fully hereinafter with reference to the accompanying drawings, in which exemplary embodiments of the invention are shown. This invention may, however, be embodied in different forms and should not be construed as limited to the embodiments set forth herein. It should be readily understood that the meaning of “on” and “over” in the present disclosure should be interpreted in the broadest manner such that “on” not only means “directly on” something but also include the meaning of “on” something with an intermediate feature or a layer therebetween, and that “over” not only means the meaning of “over” something may also include the meaning it is “over” something with no intermediate feature or layer therebetween (i.e., directly on something). In this specification, ‘connected/coupled’ represents that one component is directly coupled to another component or indirectly coupled through another component. In this specification, a singular form may include a plural form as long as it is not specifically mentioned in a sentence.

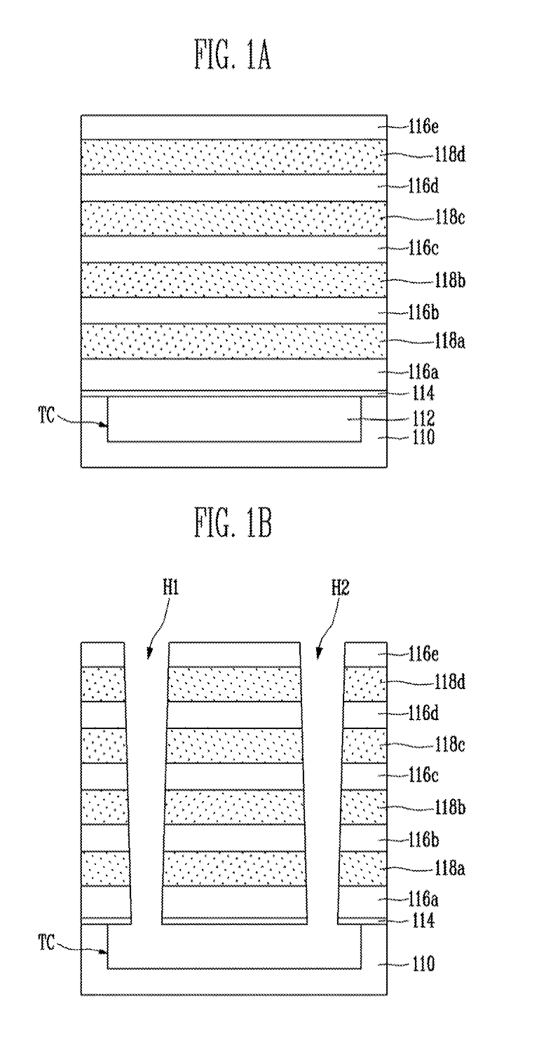

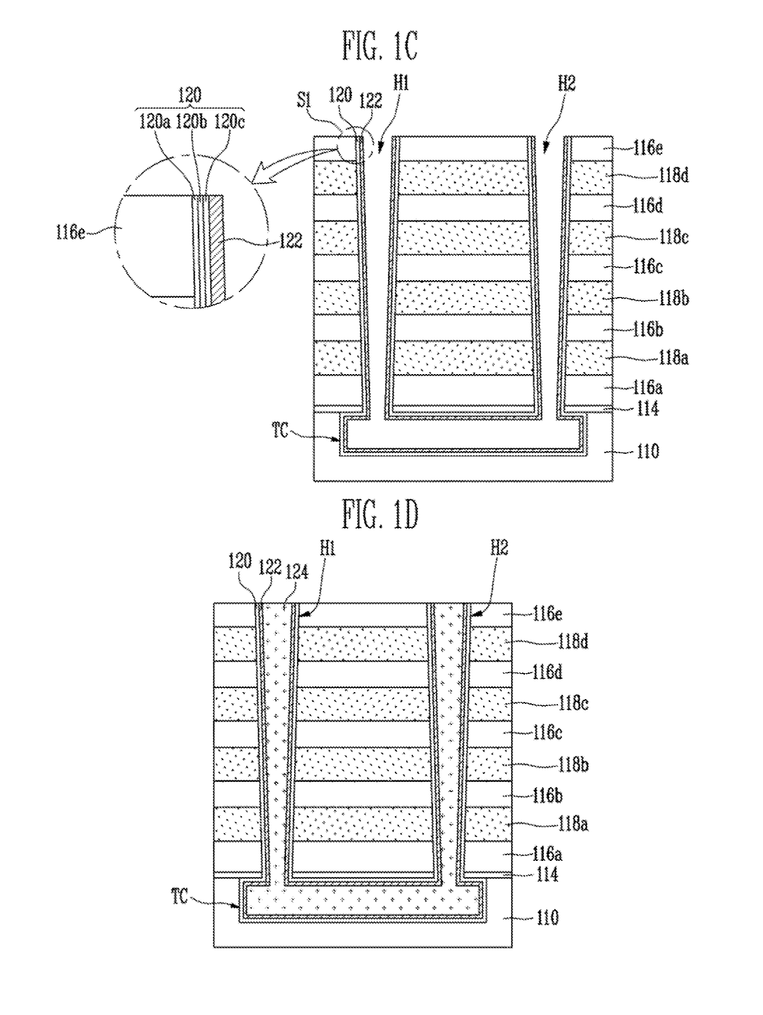

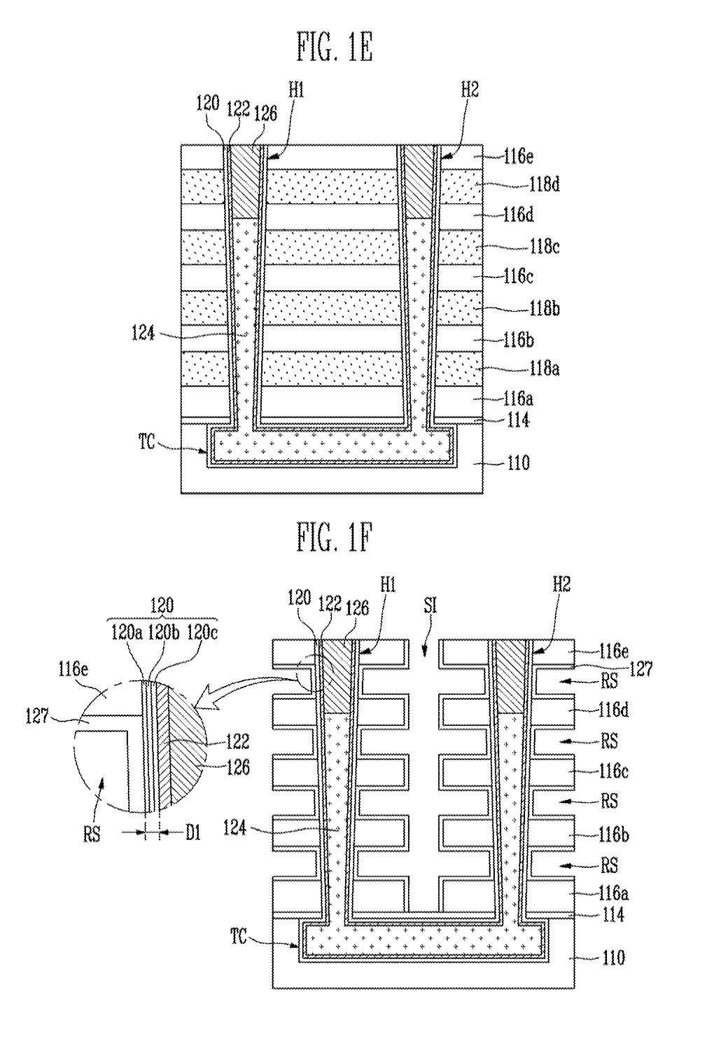

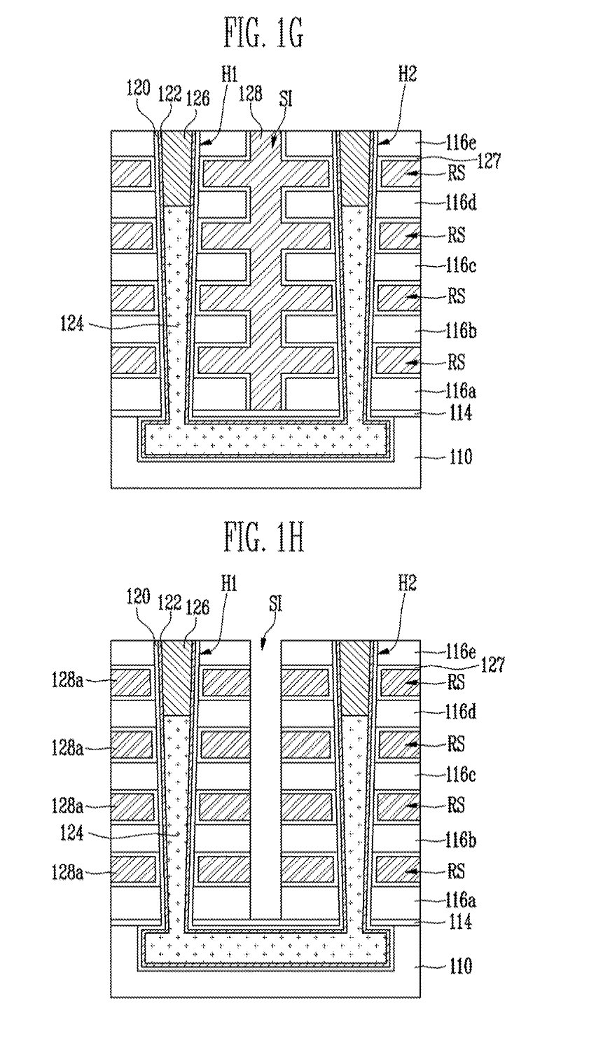

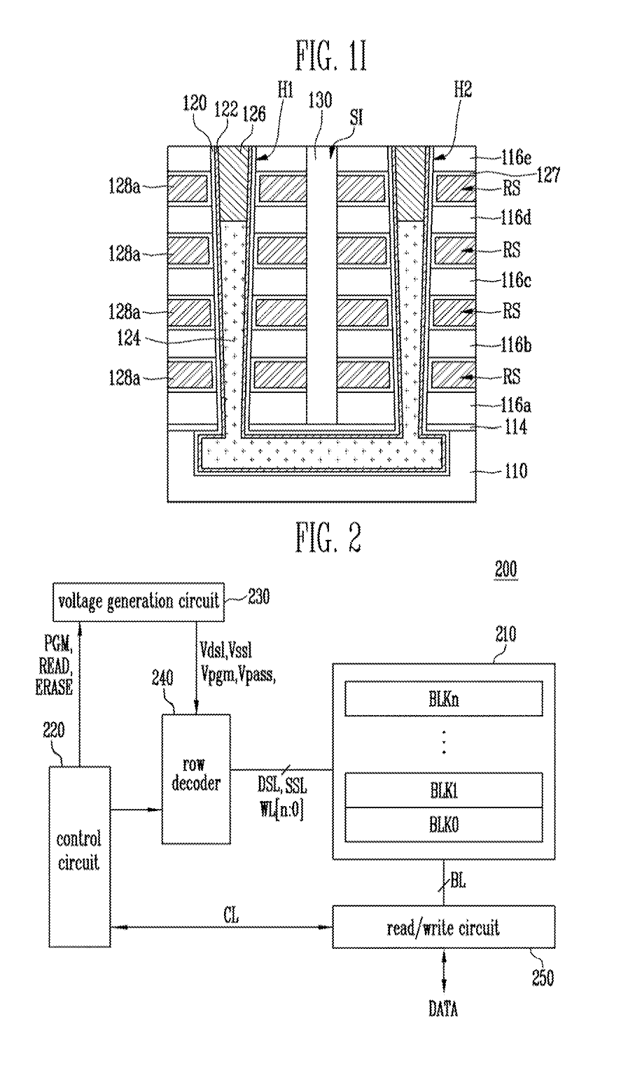

FIGS. 1A to 1I are cross-sectional views illustrating a method of fabricating a semiconductor device according to an exemplary embodiment of the present invention.

Referring to FIG. 1A, a trench TC is formed in a first pipe gate 110 formed on a semiconductor substrate, and a first sacrificial layer 112 is formed in the trench TC. For example, the first sacrificial layer 112 may include an oxide layer. A second pipe gate 114 may be further formed on the first pipe gate 110 in which the first sacrificial layer 112 is formed. First material layers 116a, 116b, 116c, 116d, and 116e and second sacrificial layers 118a, 118b, 118c, and 118d are alternately stacked on the second pipe gate 114. For example, the first material layers 116a, 116b, 116c, 116d and 116e may include an insulating material used as an interlayer insulating layer, for example an oxide layer. The second sacrificial layers 118a, 118b, 118c, and 118d include a material having a different etch selectivity from the first material layers 116a, 116b, 116c, 116d, and 116e. For example, the second sacrificial layers 118a, 118b, 118c, and 118d may include silicon nitride. In FIG. 1A, for the convenience of description, the number of stacked first material layers 116a, 116b, 116c, 116d and 116e and second sacrificial layers 118a, 118b, 118c, and 118d is relatively small, however, the stacked number may increase or decrease depending on memory devices.

Referring to FIG. 1B, vertical channel holes H1 and H2 are formed in vertical channel areas. For example, hard mask patterns (not shown) in which the vertical channel areas are opened are formed on the first material layer 116e formed in the uppermost layer, then vertical channel holes H1 and H2 are formed by an etching process, and then the hard mask patterns (not shown) are removed. In the vertical channel holes, the first vertical channel hole H1 and the second vertical channel hole H2 may form a pair. The etching process is performed until the first sacrificial layer 112 is exposed through the first vertical channel hole H1 and the second vertical channel hole H2.

Next, the first sacrificial layer 112 exposed by the first vertical channel hole H1 and the second vertical channel hole H2 is removed. Accordingly, the first vertical channel hole H1, the trench TC, and the second vertical channel hole H2 are connected to each other.

Referring to FIG. 1C, a memory stacked-layer 120 and a vertical channel layer 122 are formed along inner walls of the first vertical channel hole H1, the trench TC, and the second vertical channel hole H2. In an enlarged view of a part S1, the memory stacked-layer 120 includes a blocking layer 120a, a charge storage layer 120b, and a tunnel dielectric layer 120c. For example, the blocking layer 120a, the charge storage layer 120b, the tunnel dielectric layer 120c, and the vertical channel layer 122 are sequentially formed along the inner walls of the first vertical channel hole H1, the trench TC, and the second vertical channel hole H2.

In particular, since some parts of the blocking layer 120a is exposed when a subsequent etching process is performed, the blocking layer 120a includes a metal oxide layer instead of a commonly used silicon oxide (SiO₂) layer in order to suppress damage caused by the etching process. For example, the metal oxide layer may include Al₂O₃, HfO₃, and ZrO₃. Accordingly, the blocking layer 120a may be formed of one of Al₂O₃, HfO₃, and ZrO₃. The charge storage layer 120b may include a silicon nitride layer capable of trapping charges, and the tunnel dielectric layer 120c may include a polysilicon layer.

In addition, the vertical channel layer 122 may be formed in a tube shape along the inner wall of the memory stacked-layer 120, or formed to fill the first and second vertical channel holes H1 and H2 in which the memory stacked-layer 120 is formed.

Referring to FIG. 1D, the inside of the first vertical channel hole H1, the trench TC, and the second vertical channel hole H2 in which the vertical channel layer 122 is formed is filled with a first insulating layer 124. The first insulating layer 124 includes a silicon oxide layer or a flowable insulating material. For example, the flowable insulating material may be a partially stabilized zirconia (PSZ) layer.

Referring to FIG. 1E, after the first insulating layer 124 exposed on the first vertical channel hole H1 and the second vertical channel hole H2 is removed to a certain depth, a junction area 126 is formed by filling the area in which the first insulating layer 124 is removed with a doped polysilicon layer. For example, the doped polysilicon layer may include an N+ type polysilicon layer. The junction area 126 may reduce the resistance of areas in which select lines are formed in a subsequent process.

Referring to FIG. 1F, a slit SI is formed by etching the first material layers 116a to 116e and the second sacrificial layers 118a to 118d formed in a slit area. The slit SI is formed between rows of the vertical channel layers 122 in the row direction. As a result, sidewalls of the stacked first material layers 116a to 116e and second sacrificial layers 118a to 118d are exposed through the slit SI, and the stacked first material layers 116a to 116e and the second sacrificial layers 118a to 118d are separated through the slit SI. The width of the slit SI may be narrower than or substantially the same as that of the first or second vertical channel holes H1 or H2. For example, when the width of the slit SI is narrower than the first or second vertical channel holes H1 or H2, the slit SI may have a width of half the thickness of the blocking layer 120a. That is, since a process of additionally forming the blocking layer 120a may be omitted in a subsequent process, the width of the slit SI may be formed small as well.

Next, an etching process removes the second sacrificial layers 118a to 118d exposed by the slit SI. As a result, recesses RS exposing the blocking layer 120a disposed between the adjacent first material layers 116a to 116e are formed.

Since the first material layers 116a to 116e and second sacrificial layers 118a to 118d include materials having different etch selectivity from each other, the second sacrificial layers 118a to 118d may be selectively etched depending on an etchant.

In particular, when the second sacrificial layers 118a to 118d include a silicon nitride layer, a phosphoric acid solution is commonly used as the etchant for etching the silicon nitride layer. Although the phosphoric acid solution is mainly used for removing a nitride layer, the silicon oxide (SiO₂) layer may also be etched by the phosphoric acid solution. That is, although the silicon nitride layer is etched faster than the silicon oxide layer by the phosphoric acid solution, when the blocking layer 120a includes the silicon oxide layer, the blocking layer 120a may be damaged by the phosphoric acid solution. Accordingly, the blocking layer 120a may include a metal oxide layer instead of the silicon oxide layer in the embodiments of the present invention, as described in FIG. 1A. The metal oxide layer is not etched by the etchant for removing the silicon nitride layer (for example, the phosphoric acid solution). Even if the metal oxide layer is etched, since the etch rate of the metal oxide layer is much smaller than that of the silicon oxide layer, the etch damage of the blocking layer 120a may be suppressed while the second sacrificial layers 118a to 118d are etched.

Accordingly, since the exposure of the charge storage layer 120b through the recesses RS is prevented even when the second sacrificial layers 118a to 118d are etched, the charge storage layer 120b may be protected and reduction in thickness of the memory stacked-layer 120 may be prevented. In addition, when the blocking layer 120a includes a silicon oxide layer as usual, another blocking layer may be additionally formed in order to compensate for the etching damage, however, in this case, the cost and time increase due to the increase of the number of fabrication processes. However, since the blocking layer 120a includes a metal oxide layer according to the embodiments of the present invention, the additional process for compensating for the etching damage of the blocking layer 120a after etching the second sacrificial layers 118a to 118d may be omitted. Accordingly, the cost and time may decrease compared to when the blocking layer 120a includes a silicon oxide layer. However, the process of additionally forming the blocking layer 120a may be further performed when the thickness of the blocking layer 120a is increased or adjusted depending on the kinds of memory devices. When the blocking layer 120a is additionally formed, the blocking layer 120a may include the silicon oxide layer. Next, a barrier layer 127 is formed along inner walls of the slit SI and recesses RS. The barrier layer 127 may include a Ti/TiN layer.

Referring to FIG. 1G, the inside of the slit SI and recesses RS is filled with a conductive layer 128. The conductive layer 128 may include a polysilicon layer or a material layer having low resistance compared to the polysilicon layer and having a high work function. For example, the conductive layer 128 may include tungsten (W). When the conductive layer 128 includes a material layer having a high work function, a phenomenon of back tunneling of charges to the charge storage layer 120b through the charge blocking layer 120a may decrease. When the back tunneling phenomenon decreases, the retention characteristics of a memory cell may be improved.

Referring to FIG. 1H, the conductive layer 128 and the barrier layer 127 formed in the slit SI area are removed by an etching process. In this case, since the conductive layers 128 and the barrier layers 127 formed in the recesses RS may remain, the etching process is performed using anisotropic dry etching. Conductive layers 128a remaining in the recesses RS after removing the conductive layer 128 and barrier layer 127 formed in the slit SI become word-lines or select-lines.

Referring to FIG. 1I, the slit SI is filled with a second insulating layer 130. The second insulating layer 130 may include an oxide layer or a nitride layer.

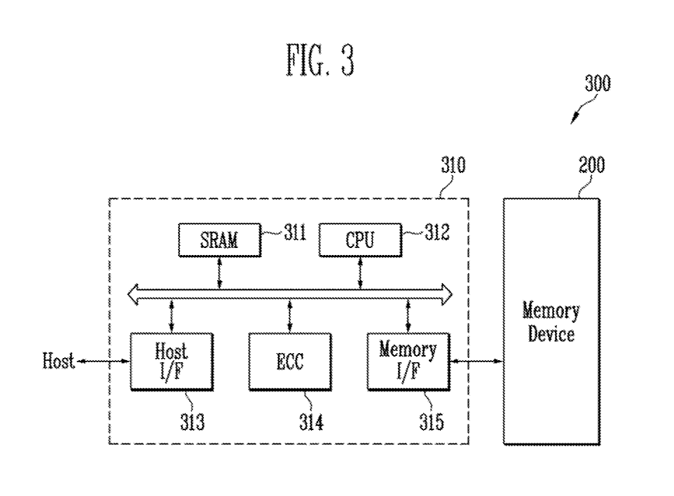

FIG. 2 is a block diagram for describing a semiconductor memory device according to an exemplary embodiment of the present invention.

Referring to FIG. 2, a semiconductor memory device 200 includes a memory cell array 210, a plurality of circuits 230, 240, and 250 configured to perform programming, read and erase operation of memory cells included in the memory cell array 210, and a control circuit configured to control the plurality of circuits 230, 240, and 250 to perform programming and read and erase operation of memory cells according to an input data.

In a NAND flash memory device, the plurality of circuits include a voltage generation circuit 230, a row decoder 240, and a read/write circuit 250.

The memory cell array 210 includes a plurality of memory blocks BLK0 to BLKn. Each of the memory blocks includes a vertical channel layer 122 protruding from a substrate, a tunnel dielectric layer 120c and charge storage layer 120b surrounding side surfaces of the vertical channel layer 122, a blocking layer 120a surrounding the charge storage layer 120b and formed of a metal oxide layer, first material layers 116a to 116e for a inter layer stacked along the blocking layer 120a and surrounding the blocking layer 120, recesses RS defined by the first material layers 116a to 116e, and conductive layers 128a filling insides of the recesses (RS).

The voltage generation circuit 230 generates a required voltage depending on a program operation signal PGM, a read operation signal READ, and an erase operation signal ERASE that are output from a control circuit 220. For example, the voltage generation circuit 230 generates a drain select voltage Vdsl to be supplied to a drain select line, a source select voltage Cssl to be supplied to a source select line, a program voltage Vpgm to be supplied to a selected word line, and a pass voltage Vpass to be supplied to a non-selected word line during a program operation.

The row decoder 240 selects a memory block according to control of the control circuit 220, transfers a drain select voltage Vdsl generated in the voltage generation circuit 230 to a drain select line DSL of the selected memory block, transfers a source select voltage Vssl to a source select line SSL of the selected memory block, transfers a program voltage Vpgm to one of selected word lines WL0 to WLn of the selected memory block, and transfers a pass voltage Vpass to the remaining non-selected word lines of the selected memory block.

The read/write circuit 250 controls the control circuit 220 and applies a program permission voltage or a program inhibit voltage to bit lines BL connected to the memory cell array 210 according to external input data. Otherwise, the read/write circuit 250 outputs data read from the memory cell array 210 according to the control of the control circuit to an external.

The control circuit 220 internally outputs a program operation signal PGM, a read operation signal READ, and an erase operation signal, and controls the row decoder 240 and the read/write circuit 250.

FIG. 3 is a block diagram schematically illustrating a memory system according to an exemplary embodiment of the present invention.

Referring to FIG. 3, a memory system 300 according to the present invention includes a semiconductor memory apparatus 200 and a memory controller 310.

The semiconductor memory apparatus 200 includes a vertical channel layer 122 protruding from a substrate, a tunnel dielectric layer 120c and charge storage layer 120b surrounding side surfaces of the vertical channel layer 122, a blocking layer 120a surrounding the charge storage layer 120b and formed of a metal oxide layer, first material layers 116a to 116e for a inter layer stacked along the blocking layer 120a and surrounding the blocking layer 120, recesses RS defined by the first material layers 116a to 116e, and conductive layers 128a filling the recesses (RS), as described in FIG. 2.

The memory controller 310 controls a data exchange between a host and the memory device. The memory controller 310 may include a processing unit 312 for controlling the overall operations of the memory system 300. In addition, the memory controller 310 may include SRAM 311 used as an operation memory of the processing unit 312. In addition, the memory controller 310 may further include a host interface 313 and a memory interface 315. The host interface 313 may have a protocol for data exchange between the memory system and the host. The memory interface 315 may connect the memory controller 310 and the semiconductor memory device 200. Furthermore, the memory controller 310 may include an error checking and correcting (ECC) block 314. The ECC block 314 may detect and correct an error of data read from the semiconductor memory device 200. Although not shown the memory system 300 may further include a read-only-memory (ROM) device storing code data for interfacing with the host. The memory system 300 may be used as a portable data storage card. Otherwise, the memory system may be implemented as a solid state disk (SSD) capable of replacing a hard disk of a computer system.

According to the present invention, the time and cost for the process of fabricating a semiconductor memory device having a vertical channel structure may be reduced, and the defects caused by an etch process during the fabrication process may be prevented. In addition, since an additional process for compensating the blocking layer may be omitted. Therefore, there is no need to increase the thickness of the memory stacked-layer with the additional process. Accordingly, increase in size of the semiconductor memory device may be prevented, and a reliability of the semiconductor memory device having a vertical channel structure may be improved.

In the drawings and specification, typical exemplary embodiments of the invention have been disclosed, and although specific terms are employed they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

What is claimed is:

1. A semiconductor memory device, comprising:
a vertical channel layer protruding from a surface of a substrate;
a tunnel insulating layer and a charge storage layer, which are surrounding the vertical channel layer;
a blocking layer surrounding the charge storage layer;
interlayer insulating layers stacked along the blocking layer; and
conductive layers interposed between the interlayer insulating layers,
wherein the blocking layer includes a metal oxide layer.

2. The semiconductor memory device of claim 1, wherein the metal oxide layer comprises a material that is not etched by an etchant for removing the sacrificial layers.

3. The semiconductor memory device of claim 2, wherein the metal oxide layer comprises Al₂O₃, HfO₃ or ZrO₃.

4. The semiconductor memory device of claim 1, further comprising:
a barrier layer formed along a surface of the charge storage layer.

5. The semiconductor memory device of claim 4, wherein the barrier layer comprises a Ti/TIN layer.

6. The semiconductor memory device of claim 1, further comprising:
a pipe gate formed in lower parts of the vertical channel layers.

7. A method of fabricating a semiconductor memory device, comprising:
alternately forming interlayer insulating layers and sacrificial layers over a substrate;
forming vertical channel holes passing through the interlayer insulating layers and sacrificial layers substantially perpendicular to the substrate;
forming blocking layers, charge storage layers, tunnel insulating layers, and vertical channel layers along inner walls of the vertical channel holes;
etching the interlayer insulating layers and the sacrificial layers to form a slit between the vertical channel layers;
removing the sacrificial layers exposed through the slit to form recesses between the interlayer insulating layers;
forming a conductive layer in the recesses; and
filling the slit with an insulating layer,
wherein the blocking layer includes a metal oxide layer.

8. The method of claim 7, wherein the metal oxide layer includes a material that is not etched by an etchant for removing the sacrificial layers.

9. The method of claim 8, where in the metal oxide layer comprises Al₂O₃, HfO₃ or ZrO₃.

10. The method of claim 7 wherein the formation of the vertical channel holes comprises:
forming a hard mask pattern opening vertical channel areas on a structure in which the interlayer insulating layers and the sacrificial layers are formed;
forming the vertical channel holes exposing the substrate by performing an etch process using the hard mask pattern as an etch mask; and
removing the hard mask pattern.

11. The method of claim 7, wherein the slit is formed in a row direction between the vertical channel layers adjacent to each other.

12. The method of claim 11, wherein the width of the slit is narrower than or substantially the same as the width of the vertical channel holes.

13. The method of claim 12, wherein, if the width of the slit is narrower than the width of the vertical channel holes, the width of the slit is about half the thickness of the blocking layer.

14. The method of claim 7, wherein the formation of the recesses comprises performing a wet etch process using a phosphoric acid solution.

15. The method of claim 7, further comprising:
forming barrier layers along sidewalls of the recesses between the formation of the slit and the formation of the conductive layers.

16. The method of claim 15, wherein the barrier layers comprises a Ti/TiN layer.

17. The method of claim 7, wherein the formation of the conductive layers comprises:
forming the conductive layers filling the slit and the recesses; and
removing the conductive layer formed in the slit, and leaving the conductive layer formed in the recesses.

18. The method of claim 7, wherein the conductive layer comprises tungsten.

19. The method of claim 7, further comprising:
forming a pipe gate over the substrate before alternately forming the interlayer insulating layers and sacrificial layers.

20. A memory system, comprising:
a semiconductor memory device including a vertical channel layer protruding from a surface of a substrate, a tunnel insulating layer and a charge storage layer, which are surrounding the vertical channel layer, a blocking layer surrounding the charge storage layer, interlayer insulating layers stacked along the blocking layer, and conductive layers interposed between the interlayer insulating layers; and
a memory controller controlling the semiconductor memory device,
wherein the blocking layer includes a metal oxide layer.
